(19) United States
(12) Patent Application Publication
(10) Pub. No.: US 2012/0267748 A1
(43) Pub. Date: Oct. 25, 2012

(54) SEMICONDUCTOR DEVICE INCLUDING SCHOTTKY BARRIER JUNCTION AND PN JUNCTION

(75) Inventor: Tohru SUZUKI, Niiza-shi (JP)

(73) Assignee: Sanken Electric Co., Ltd., Niiza-shi (JP)

(21) Appl. No.: 13/447,389

(22) Filed: Apr. 16, 2012

(30) Foreign Application Priority Data
Apr. 21, 2011 (JP) 2011-095208

(51) Int. Cl. H01L 29/47

(52) U.S. Cl. 257/471; 257/E29.148

(57) ABSTRACT

A semiconductor device includes a first conductivity-type semiconductor stack including the recesses which extend from a first principal surface toward a second principal surface and have bottoms not reaching the second principal surface, the second conductivity-type anode regions which are embedded at a distance from one another in the first principal surface, each of which has a part of an outer edge region exposed to a side surface of the corresponding recess, an anode electrode which is provided on the first principal surface of the semiconductor stack to form a Schottky barrier junction with the semiconductor stack in a region where the plurality of anode regions are not formed and form ohmic junctions with the anode regions; and a cathode electrode provided on the second principal surface of the semiconductor stack.

### CROSS REFERENCE TO RELATED APPLICATIONS AND INCORPORATION BY REFERENCE

This application is based upon and claims the benefit of priority from prior Japanese Patent Application P2011-095208 filed on Apr. 21, 2011; the entire contents of which are incorporated by reference herein.

### BACKGROUND OF THE INVENTION

1. Field of the Invention

The present invention relates to a semiconductor device including a Schottky barrier junction and a pn junction and having a rectifying function.

2. Description of the Related Art

The MPS (merged PIN Schottky) structure including a Schottky barrier junction and a pn junction is known as a structure to improve the forward surge current capacity in silicon carbide (SiC) Schottky barrier diodes and the like. Compared with a single SBD, the MPS structure allows large surge current exceeding the rated current to flow with a small voltage drop because of the bipolar operation of the pn junction diode. This improves the forward surge current capacity.

Since the MPS structure includes the pn junction, the area of the Schottky barrier junction in the MPS structure is smaller than that in a SiC Schottky barrier diode of the same chip size. Accordingly, a semiconductor device of the MPS structure has a forward voltage drop larger than that of the SiC Schottky barrier diode.

In order to reduce the forward voltage drop, it is effective to reduce the area of the pn junction. However, if the area of the pn junction is reduced, the voltage applied to the pn junction does not exceed voltage needed for the pn junction diode to perform bipolar operation in some cases. This causes a problem that the forward surge current capacity cannot be improved.

### SUMMARY OF THE INVENTION

An aspect of the present invention is a semiconductor device. The semiconductor device includes a first conductivity-type semiconductor stack including a plurality of recesses which extend from a first principal surface toward a second principal surface and have bottoms not reaching the second principal surface, the first and second principal surfaces facing each other; a plurality of second conductivity-type anode regions which are embedded at a distance from one another in the first principal surface, each of which has a part of an outer edge region exposed to a side surface of the corresponding recess; an anode electrode which is provided on the first principal surface of the semiconductor stack to form a Schottky barrier junction with the semiconductor stack in a region where the plurality of anode regions are not formed and form ohmic junctions with the plurality of anode regions; and a cathode electrode provided on the second principal surface of the semiconductor stack.

### BRIEF DESCRIPTION OF THE DRAWINGS

FIG. 1 is a schematic cross-sectional view showing a structure of a semiconductor device according to a first embodiment of the present invention.

FIG. 2 is a schematic view showing a path of forward current of the semiconductor device according to the first embodiment of the present invention.

FIG. 3 is a schematic view showing a path of forward current of a semiconductor device of a comparative example.

FIG. 4 is a graph showing forward current-voltage characteristics of the semiconductor device according to the first embodiment of the present invention and the semiconductor device of the comparative example.

FIG. 5 is a schematic cross-sectional view showing a structure of a semiconductor device according to a second embodiment of the present invention.

FIG. 6 is a schematic cross-sectional view showing a structure of a semiconductor device according to another embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified. In the following descriptions, numerous specific details are set forth such as specific signal values, etc., to provide a thorough understanding of the present invention. However, it will be obvious to those skilled in the art that the present invention may be practiced without such specific details.

### First Embodiment

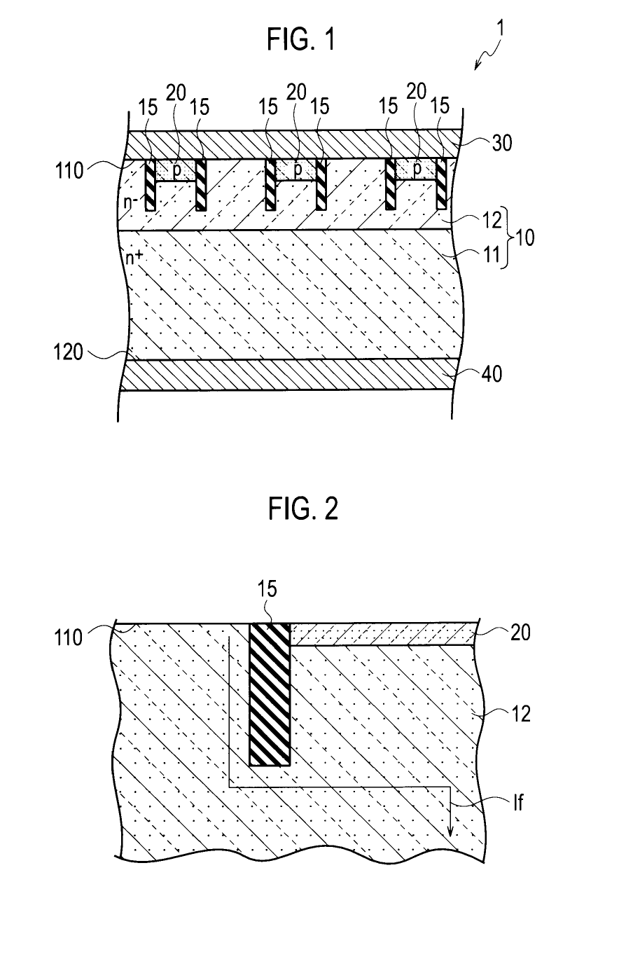

As shown in FIG. 1, a semiconductor device 1 according to a first embodiment of the present invention includes a first conductivity-type semiconductor stack 10, a plurality of second conductivity-type anode regions 20, an anode electrode 30, and a cathode electrode 40. In the first conductivity-type semiconductor stack 10, a plurality of recesses 15 are formed extending from a first principal surface 110 to a second principal surface 120. The first and second principal surfaces 110 and 120 face each other. The anode regions 20 are embedded in the first principal surface 110 of the semiconductor stack 10 with a distance from one another. The anode electrode 30 is provided on the first principal surface 110 of the semiconductor stack 10. The cathode electrode 40 is provided on the second principal surface 120 of the semiconductor stack 10. As shown in FIG. 1, the bottoms of the recesses 15 do not reach the second principal surface 120. A part of the outer edge of each anode region 20 is exposed in the side surface of the corresponding recess 15. The anode electrode 30 forms Schottky barrier junctions with the semiconductor stack 10 in a region where the anode regions 20 are not formed and forms ohmic junctions with the anode regions 20.

The first and second conductivity types are opposite to each other. To be specific, the first conductivity type is n-type while the second conductivity type is p-type, or the first conductivity type is p-type while the second conductivity type is n-type. In the following description, the first conductivity type is n-type, and the second conductivity type is p-type.

In a part where the anode regions 20 are not formed in the region where the semiconductor stack 10 is in contact with the anode electrode 30, Schottky barrier diodes are formed. The regions where the Schottky barrier diodes are formed are referred to as the ‘Schottky barrier junction portions’ below. In the regions where the semiconductor stack 10 is in contact with the anode regions 20, pn junction diodes are formed. The regions where the pn junction diodes are formed are referred to as the ‘pn junction portions’ below.

As described above, the semiconductor device 1 has the MPS structure including Schottky barrier junctions and pn junctions. In the semiconductor 1 shown in FIG. 1, the recesses 15 are formed in the boundaries between the pn junction portions and the Schottky barrier junction portions. In other words, the side end surfaces of the anode regions 20 are exposed in the side surfaces of the recesses 15.

The semiconductor stack 10 shown in FIG. 1 is a stack of a semiconductor substrate 11 and a semiconductor layer 12. The semiconductor substrate 11 is in contact with the cathode electrode 40 by the second principal surface 120, and the semiconductor layer 12 is in contact with the anode electrode 30 by the first principal surface 110. In the example shown in FIG. 1, the recesses 15 extending from the first principal surface 110 into the semiconductor stack 10 remain within the semiconductor layer 12 and do not reach the semiconductor substrate 11.

The semiconductor substrate 11 can be composed of a silicon carbide (SiC) substrate, a gallium nitride (GaN) substrate, or the like, for example. The semiconductor layer 12 is an epitaxial layer grown on the semiconductor substrate 11 or the like.

The semiconductor substrate 11 is composed of a SiC substrate having a film thickness of 300 to 400 μm and an impurity concentration of about 1×10¹⁸ to 1×10¹⁸ cm⁻³, for example. The semiconductor layer 12 is composed of an epitaxially grown SiC layer having a film thickness of 5 to 15 μm and an impurity concentration of about 1×10¹⁵ to 1×10¹⁷ cm⁻³, for example.

Each of the anode regions 20 has a thickness of 0.1 to 1.0 μm and an impurity concentration of about 1×10¹⁷ to 1×10¹⁹ cm⁻³, for example. The p-type impurities doped into the anode regions 20 are aluminum or the like.

The anode electrode 30 can be made of a metallic material which forms Schottky barrier junctions in the interface with the semiconductor layer 12 and forms an ohmic junction in the interface with each anode region 20. The cathode electrode 40 can be made of a metallic material which forms an ohmic junction with the semiconductor substrate 11.

In the semiconductor device 1, if forward voltage is applied across the anode and cathode electrodes 30 and 40, forward current If flows from the anode electrode 30 to the cathode electrode 40 through the semiconductor stack 10. At this time, as shown in FIG. 2, while the forward voltage is low, the forward current If having passed through the Schottky barrier junction portion travels along the recess 15 in the thickness direction of the semiconductor stack 10 and then flows to the cathode electrode 40 through a part of the semiconductor layer 12 under the pn junction portion. This is because the pn junction diode does not perform bipolar operation and does not allow the forward current If to flow through the pn junction portion while the forward voltage drop is small.

The recesses 15 are filled with insulating film such as silicon oxide film, for example. This is for the purpose of preventing the forward current If from flowing from a part of the semiconductor layer 12 under the Schottky barrier junction portion toward a part of the semiconductor layer 12 under the pn junction region across the recess 15. Accordingly, as long as the forward current If can be prevented from flowing within the recesses 15, the material embedded in the recesses 15 is not limited to the insulating film, or each recess 15 may include a cavity inside.

In a general semiconductor device including the MPS structure (hereinafter, referred to as an MPS device), the bipolar operation of the pn junction diodes improves the forward surge current capacity. To be specific, holes are injected from the p-type semiconductor layer to the n-type semiconductor layer to make the concentration of electrons in the n-type semiconductor layer higher than the original impurity concentration. This allows large current to flow through the MPS device, thus improving the forward surge current capacity.

On the other hand, since the MPS device includes the pn junction portions, the area of the Schottky barrier junction portions of the MPS device is smaller than that of an SiC Schottky barrier diode of the same chip size. Accordingly, the forward voltage drop Vf at the rated operation of the MPS device is larger than that of the SiC Schottky barrier diode.

The forward voltage drop of the MPS device is, therefore, required to be small, and for reduction of the forward voltage drop, it is effective to reduce the area of the pn junction portion.

However, in order for each pn junction diode of the MPS device to perform bipolar operation, as described later, the width of the pn junction portion parallel to the junction surface (hereinafter, just referred to as a width) needs to be not less than a certain level. If the width of the pn junction portion is reduced to less than a certain limit, the pn junction diode does not perform bipolar operation, and the forward surge current capacity cannot be improved. Hereinafter, a description is given of a relation between the width of the pn junction portion and the bipolar operation of the pn junction portion.

The bipolar operation of the pn junction diode of the MPS device requires application of forward voltage not less than the minimum voltage needed to operate the pn junction diode (hereinafter, referred to as threshold voltage) to the pn junction. The voltage applied to the pn junction of the MPS device depends on the voltage drop due to current flowing from the Schottky barrier junction portion under the anode region 20. Accordingly, the narrower the width of the pn junction portion, the lower the voltage applied to the pn junction.

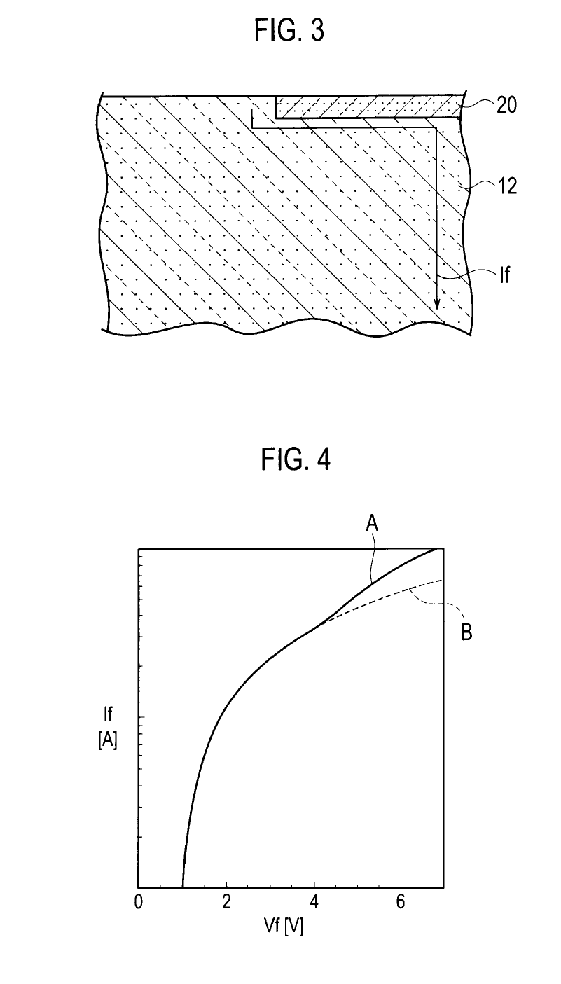

In an MPS device not including the recesses 15 as shown in FIG. 3, voltage applied to the pn junction is 0 V in the outer edge of the pn junction portion, that is, a region of the pn junction portion closest to the Schottky barrier junction portion. As shown in FIG. 3, the forward current If flows under the anode region 20 through the semiconductor stack 10. Accordingly, the longer the distance from the Schottky barrier junction portion, the larger the voltage drop due to the forward current If flowing under the pn junction portion. In other words, the longer the distance from the boundary with the Schottky barrier junction portion, the larger the voltage applied to the pn junction. Therefore, the voltage applied to the pn junction is maximized at the center of the pn junction portion.

When the voltage drop due to the forward current If flowing under the pn junction portion exceeds the threshold voltage needed for bipolar operation, the pn junction diode starts to perform bipolar operation. Accordingly, if the width of the pn junction portion is narrower than the certain limit, the voltage drop due to the forward current If cannot exceed the threshold voltage, and the pn junction diode does not perform bipolar operation.

As described above, in the MPS device not including the recesses 15, the voltage drop at the pn junction portion is reduced if the area of the pn junction portion is reduced in order to reduce the forward voltage drop Vf. This could prevent the pn junction diode from performing the bipolar operation. If the pn junction diode does not perform the bipolar operation, the effect of the MPS device on improving the forward surge current capacity becomes extremely small.

However, in the semiconductor device 1 shown in FIG. 1, since the recesses 15 are formed in the first principal surface 110 of the semiconductor stack 10, the forward current If causes large voltage drop. To be specific, as shown in FIG. 2, the forward current If flowing from the Schottky barrier junction portion to the semiconductor stack 10 flows along the side surface of each recess 15 in the direction vertical to the first principal surface, travels under the bottom of the recess 15, and then flows under the pn junction portion.

In the MPS device shown in FIG. 3 not including the recesses 15, the voltage drop due to the forward current If at the pn junction portion depends on only the distance from the boundary with the Schottky barrier junction portion. On the other hand, in the semiconductor device shown in FIG. 1, the voltage drop at the pn junction portion depends on the sum of the distance from the boundary with the Schottky barrier junction portion and the depth of the recess 15. In other words, forming the recess 15 in the first principal surface 110 of the semiconductor stack 10 increases the current path of the forward current If by the depth of the recess 15.

Accordingly, the voltage applied to the pn junction portion of the semiconductor device 1 at a certain region is equal to the sum of the voltage drop along the side surface of the recess 15 in the depth direction and the voltage drop of the pn junction portion in the width direction. The voltage applied to the outermost edge portion of the pn junction portion, for example, is equal to the voltage drop caused by the forward current If flowing along the side surface of the recess 15. In such a manner, the voltage drop of the pn junction portion of the semiconductor device 1 is larger than that of the semiconductor device not including the recesses 15.

As described above, in the semiconductor device 1, the pn junction diode performs bipolar operation even if the width of the pn junction portion is reduced. The depth of the recesses 15 is set based on the width of the pn junction portion and the like so that the voltage drop at the pn junction portion exceeds the threshold voltage needed for the bipolar operation. Preferably, the depth of the recesses 15 is not less than the thickness of the anode regions 20. The width of the recesses 15 should be at least large enough to isolate the pn junction portion from the Schottky barrier junction portion, which is about 0.1 to 1.0 μm, for example.

Hereinafter, concerning the characteristics of an MPS device with a withstand voltage of 1500 V, the results of comparison between the presence and absence of the recesses 15 are shown. FIG. 4 shows forward current-voltage characteristics of the semiconductor device 1 which includes the recesses 15 (shown in FIG. 1) and a comparative example which includes no recesses (shown in FIG. 3). In FIG. 4, the forward current-voltage characteristics of the semiconductor device 1 and the comparative example not including the recesses are indicated by characteristics A and B, respectively. In the semiconductor device 1 and comparative example, the semiconductor substrates 11 have thicknesses of 360 μm and n-type impurity concentrations of 2×10¹⁸ cm⁻³. The semiconductor layers 12 have thicknesses of 10 μm and n-type impurity concentrations of 8×10¹⁵ cm⁻³. The anode regions 20 have thicknesses of 0.5 μm and p-type impurity concentrations of 1×10¹⁹ cm⁻³. The recesses 15 have widths of 0.5 μm and depths of 8 μm.

As shown in FIG. 4, the characteristic A of the semiconductor device 1 is greatly different from the characteristic B of the comparative example when the forward voltage drop Vf is around 4V or more. To be specific, the forward current If of the semiconductor device 1 is larger than that of the comparative example for the same forward voltage Vf. Such a difference is caused because the pn junction diode of the semiconductor device 1 starts the bipolar operation when the forward voltage drop Vf reaches around 4 V while the pn junction diode of the comparative example does not perform the bipolar operation. In other words, in the semiconductor device 1, the increase in forward voltage drop Vf is suppressed compared with the comparative example, and large current is allowed to flow with the small forward voltage drop Vf.

As described above, in the semiconductor device 1 according to the first embodiment of the present invention, the recesses 15 are formed in the outer edge region of the pn junction portion, and the forward current If flows a long current path from the Schottky barrier junction portion to a part of the semiconductor stack 10 under the pn junction portion. Accordingly, the forward current If causes large voltage drop, and the voltage applied to the pn junction is larger than that in the case where the recesses 15 are not formed.

In the semiconductor device 1, therefore, the voltage drop at the pn junction portion exceeds the threshold voltage even if the width of the pn junction portion is reduced in order to prevent the forward voltage drop Vf from increasing. The pn junction diode therefore performs bipolar operation, and the effect on improving the forward surge current capacity is not reduced. In other words, according to the semiconductor device 1, it is possible to implement a semiconductor device having a high forward surge current capacity with an increase in the forward voltage drop Vf prevented.

Moreover, if the depth of the recesses 15 is more than the thickness of the anode regions 20, the pn junction diodes can be caused to operate without increasing the width of the recesses 15. It is therefore possible to reduce the chip size of the semiconductor device 1 with a high forward surge current capacity.

### Second Embodiment

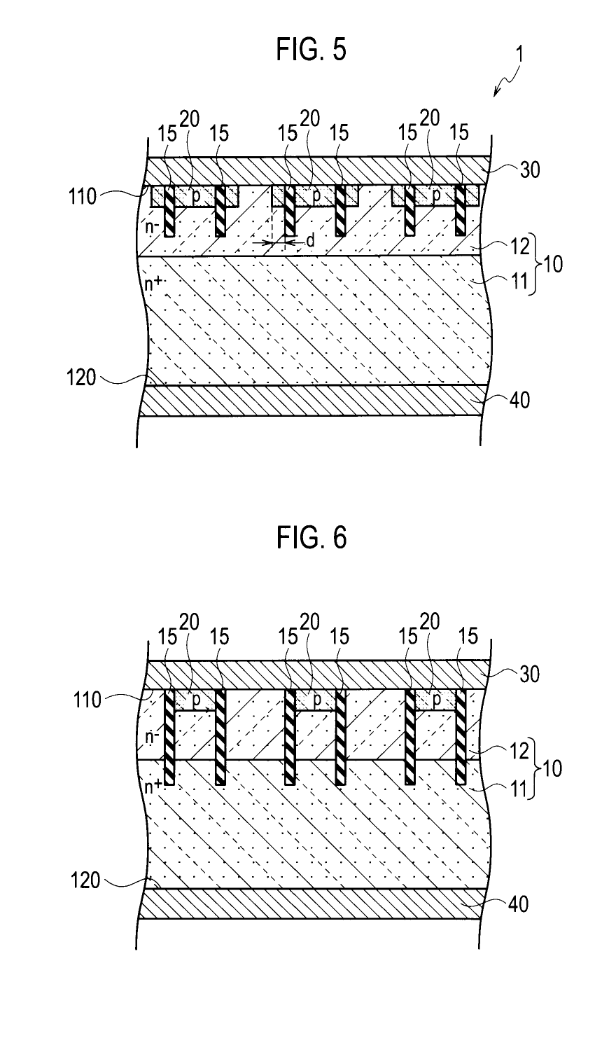

In the semiconductor device 1 shown in FIG. 1, the side end surfaces of the anode regions 20 are exposed to the side surfaces of the recesses 15. In other words, the recesses 15 are formed in the boundaries between the pn junction portions and the Schottky barrier junction portions. However, as shown in FIG. 5, each recess 15 may be formed so as to penetrate the outer edge region of the corresponding anode region 20.

In the MPS device, the reverse leakage current is reduced by covering the Schottky barrier junction with the depletion layer caused by the pn junction. It is therefore preferable that the width of each Schottky barrier junction portion is narrow. In such a case, in order to prevent the forward voltage drop Vf from increasing, the width of the pn junction portion needs to be narrowed according to the narrowed width of the Schottky barrier junction portion.

In a semiconductor device 1 according to a second embodiment shown in FIG. 5, in a similar manner to the semiconductor device 1 shown in FIG. 1, since the recesses 15 are formed in the first principal surface 110 of the semiconductor stack 10, the forward surge current capacity thereof is high even if the width of the pn junction portion is narrowed. Furthermore, the recesses 15 are formed to penetrate the pn junction portions, so that a part of each pn junction portion is located between the corresponding recess 15 and Schottky barrier junction portion of the semiconductor device 1 shown in FIG. 5. Accordingly, the depletion layer extending from the pn junction portion at reverse bias expands to the Schottky barrier junction portion.

In the semiconductor device 1 shown in FIG. 5, therefore, the Schottky barrier junction is covered with the depletion layer caused at the pn junction, so that the reverse leakage current is reduced.

Each anode region 20 and the anode electrode 30 form an ohmic junction on both sides of the corresponding recess 15. The distance d between an outer edge of each anode region 20 and the corresponding recess 15 is set so that the voltage drop at the pn junction exceeds the threshold value needed for the bipolar operation. The distance d is also set so that the depletion layer extending from the pn junction portion covers the Schottky barrier junction portion. The distance d is set to the thickness of the anode region 20 or more, for example.

According to the semiconductor device 1 of the second embodiment of the present invention, in the case where the width of the Schottky barrier junction portion is narrowed for the purpose of reducing the reverse leakage current, even if the width of the pn junction portion is narrowed for the purpose of preventing the forward voltage drop Vf from increasing, the voltage drop at the pn junction portion exceeds the threshold voltage. This allows the pn junction diode to perform bipolar operation, thus not reducing the effect on improving the forward surge current capacity. According to the semiconductor device 1 shown in FIG. 5, it is possible to implement a semiconductor device with high forward surge current capacity with an increase in the forward voltage drop Vf prevented and the reverse leakage current reduced. The others are substantially the same as those of the first embodiment, and the overlapping description is omitted.

### Other Embodiments

The above description of the first and second embodiments shows the examples in which the depth of the recesses 15 is shorter than the thickness of the semiconductor layer 12 and does not reach the semiconductor substrate 11. However, as shown in FIG. 6, the recesses 15 may be configured to penetrate the semiconductor layer 12 so that the bottom of each recess 15 reach the inside of the semiconductor substrate 11.

Various modifications will become possible for those skilled in the art after receiving the teachings of the present disclosure without departing from the scope thereof.

What is claimed is:

1. A semiconductor device, comprising:
a first conductivity-type semiconductor stack including a plurality of recesses which extend from a first principal surface toward a second principal surface and have bottoms not reaching the second principal surface, the first and second principal surfaces facing each other;
a plurality of second conductivity-type anode regions which are embedded at a distance from one another in the first principal surface, each of which has a part of an outer edge region exposed to a side surface of the corresponding recess;
an anode electrode which is provided on the first principal surface of the semiconductor stack to form a Schottky barrier junction with the semiconductor stack in a region where the plurality of anode regions are not formed and form ohmic junctions with the plurality of anode regions; and
a cathode electrode provided on the second principal surface of the semiconductor stack.

2. The semiconductor device according to claim 1, wherein
the semiconductor stack has a structure including:
a semiconductor substrate in contact with the cathode electrode; and
a semiconductor layer which is in contact with the anode electrode and has an impurity concentration lower than that of the semiconductor substrate, the semiconductor substrate and semiconductor layer being stacked on each other, and
the bottoms of the recesses do not reach the semiconductor substrate.

3. The semiconductor device according to claim 1, wherein side end surfaces of the plurality of anode regions are exposed to the respective recesses.

4. The semiconductor device according to claim 1, wherein each of the recesses is formed so as to penetrate the outer edge region of the corresponding anode region.

5. The semiconductor device according to claim 1, wherein each of the recesses is filled with an insulating film.
